(19) United States
(12) Patent Application Publication
(10) Pub. No.: US 2020/0212241 A1
(43) Pub. Date: Jul. 2, 2020

(54) HIGH EFFICIENT PHOTOVOLTAIC MODULE WITH CUT CELLS AND FABRICATING METHOD THEREOF

(71) Applicant: Worldwide Energy and Manufacturing (Nantong) Co., Ltd., Rugao City (CN)

(72) Inventors: Jianjun WANG, Rugao City (CN); Zhaowei NING, Rugao City (CN); Tao FENG, Rugao City (CN); Congwu LIANG, Rugao City (CN); Jianchao ZHANG, Rugao City (CN); Taohua HUANG, Rugao City (CN); Yun SHI, Rugao City (CN); Dong TANG, Rugao City (CN)

(21) Appl. No.: 16/707,463

(22) Filed: Dec. 9, 2019

(30) Foreign Application Priority Data
Dec. 26, 2018 (CN) 201811600056.5

(51) Int. Cl. H01L 31/056; H01L 31/048; H01L 31/049; H01L 31/05; H01L 31/18

(52) U.S. Cl. CPC H01L 31/056; H01L 31/0481; H01L 31/1876; H01L 31/0512; H01L 31/049

(57) ABSTRACT

A high efficient photovoltaic module with cut cells including: the surface glass layer, the upper encapsulation layer, the solar cell string layer, the lower encapsulation layer, and the back plate. The solar cell string layer includes a plurality of solar cell strings, each solar cell string including a plurality of solar cells connected by using a first electric conductor and a second electric conductor. The plurality of solar cells is connected in series by the first electric conductor on front sides. The plurality of solar cells is connected in series by the second electric conductor on back sides.

### CROSS-REFERENCE TO RELATED APPLICATIONS

This application claims the benefit of priority of Chinese Application No. 201811600056.5, titled “HIGH EFFICIENT PHOTOVOLTAIC MODULE WITH CUT CELLS AND FABRICATING METHOD THEREOF,” filed on Dec. 26, 2018, which is hereby incorporated by reference in its entirety.

### BACKGROUND

### Technical Field

The disclosure relates to the technical field of solar energy technologies, and in particular, to a high efficient photovoltaic module with cut cells and fabricating method thereof.

### Description of the Related Art

As a clean and renewable new energy source, solar energy has received increasingly more attention and is applied more widely. At present, one of the most important applications of solar energy is photovoltaic power generation. The photovoltaic power generation uses the photovoltaic effect to directly convert solar energy into electrical energy. Basic units of the photovoltaic power generation are solar cells. In some embodiments, a plurality of solar cells can form a solar cell module, and solar cell modules are connected to form an overall current output.

In some embodiments, photovoltaic module can be composed of tempered glass, solar cells and a back plate. Further, an EVA encapsulation material can be provided between the tempered glass and the solar cells, and between the solar cells and the back plate. However, in the encapsulation process of the photovoltaic module, a certain encapsulation-caused power loss can be generated, so that the actual output power of the encapsulated module is less than the sum of the power of all the cells. In general, the encapsulation-caused loss can be mainly classified into the optical loss and the electrical loss. Since silicon solar cell generally has a spectral response range of 300 nm to 1100 nm, any factor that reduces the light in this wave band entering the cell can cause the optical loss. For example, absorption and reflection of light by the tempered glass and the EVA, blocking of light by the solder strip part, and so on can cause a certain optical loss. In addition, the mismatch of the electrical properties of the solar cells, the resistances of the solder strip, a bus bar and a junction box, and the contact resistance between different materials can also cause a certain electrical loss. The power loss generated by the resistance can be expressed by a formula P=I2*R, and therefore it can be seen that both current reduction and resistance reduction can reduce the power loss.

Therefore, how to minimize the power loss in the module encapsulation process and increase the output power and the conversion efficiency of the module are technical problems that need to be solved by a person skilled in the art at present.

### SUMMARY

Embodiments of the disclosure provide a solution for the above problems, including decreasing the optical loss by increasing the reflection of light in an electric conductor region and a gap region of solar cells, decreasing the electrical loss by reducing the internal current and series resistance of a module, and ultimately increasing the output power and the conversion efficiency of the module to a large degree.

In some embodiments, a high efficient photovoltaic module with cut cells in the disclosure can include: a surface glass layer, an upper encapsulation layer, a solar cell string layer, a lower encapsulation layer, and a back plate disposed sequentially from top to bottom, wherein the solar cell string layer can include a plurality of solar cell strings; each solar cell string can include a plurality of solar cells connected by using a first electric conductor and a second electric conductor; the solar cells can be cut cells; the solar cells can be connected in series by the first electric conductor on front sides, and the solar cells can be connected in series by the second electric conductor on back sides.

For example, the solar cells in the solar cell string can include P-type cells and N-type cells; the P-type cells and the N-type cells can be arranged alternately; the P-type cell and the N-type cell adjacent to each other can be connected to each other by the first electric conductor on the front sides thereof and can be connected to each other by the second electric conductor on the back sides thereof.

In some embodiments, the first electric conductor and the second electric conductor have different cross sections, and the cross-sectional area of the first electric conductor can be smaller than the cross-sectional area of the second electric conductor.

For example, the first electric conductor and the second electric conductor can be tin-coated copper strips or conductive paste.

In some embodiments, a front side of the first electric conductor can be provided with a reflective film.

For example, the solar cell can be a half-cell or a 1/n-cell (n is greater than or equal to 3), and the solar cells in the same solar cell string have the same size.

In some embodiments, the upper encapsulation layer and lower encapsulation layer can be made from ethylene vinyl acetate copolymer, polyolefin, polyvinyl butyral, or silicone.

For example, a fabricating method of the photovoltaic module can include the following steps of:

(1) alternately arranging a plurality of P-type cut cells and N-type cut cells, using a first electric conductor to achieve connection between adjacent cells on front sides, using a second electric conductor to achieve connection between the adjacent cells on back sides, and connecting the solar cells in series to form a solar cell string;

(2) laying a surface glass layer, an upper encapsulation layer, a plurality of solar cell strings, a lower encapsulation layer, and a back plate sequentially from bottom to top, and connecting the solar cell strings by using metal components; and

(3) placing the stacked component layers into a laminating machine and laminating the layers in high-temperature vacuum, cross-linking and curing the upper encapsulation layer and the lower encapsulation layer, and bonding the material and component layers into a whole to obtain the photovoltaic module.

The disclosure has the following beneficial effects:

A high efficient photovoltaic module with cut cells and a fabricating method provided in the disclosure can reduce the power loss in a module encapsulation process by reducing the electrical loss and the optical loss. In terms of reducing the electrical loss, the operating current of the module can be reduced by using cut cells, thereby reducing the power loss caused by the resistance. By using the P-type cells in combination with the N-type cells, the connection between the cells can be simplified, and adjacent cells can be connected on the same side. Since the second electric conductor can be used for connection on the back sides of the cells, the second electric conductor with a larger cross-sectional area can be used to reduce the series resistance of the module, thereby further reducing the electrical loss caused by the resistance. In terms of reducing the optical loss, the reflective film disposed on the front side of the first electric conductor can enable most of the light emitted to this region to be reflected to the surface of the solar cell and reabsorbed for use, thereby reducing the optical loss caused by blocking of light by the first electric conductor. The cells in the module can be cut cells; therefore, a larger gap area exists between the cells, and the reflection of light in this region can be increased, thereby further reducing the optical loss. Therefore, the reduction of the electrical loss and optical loss in the module encapsulation process can increase the maximum output power and the conversion efficiency of the module

The above description is merely an overview of the technical solutions of this disclosure. In order for people skilled in the art to better understand the technical means of the disclosure so that the technical solutions may be implemented more clearly and easily, the above description, other objectives, features, and advantages of the disclosure are illustrated in the following content of the specification. The embodiments of the disclosure are specifically described in what follows.

### BRIEF DESCRIPTION OF THE DRAWINGS

The accompanying drawings illustrated herein are to provide a further understanding of the disclosed embodiments and constitute a part of the disclosure. Illustrative embodiments of the disclosure and their descriptions are intended to explain the disclosed embodiments rather than unduly limit the embodiments.

FIG. 1 is a cross-sectional diagram of a high efficient photovoltaic module with cut cells according to some embodiments of the disclosure; and

FIG. 2 is a partial schematic diagram of a high efficient photovoltaic module with cut cells according to some embodiments of the disclosure.

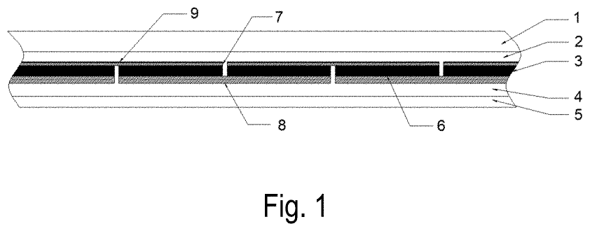

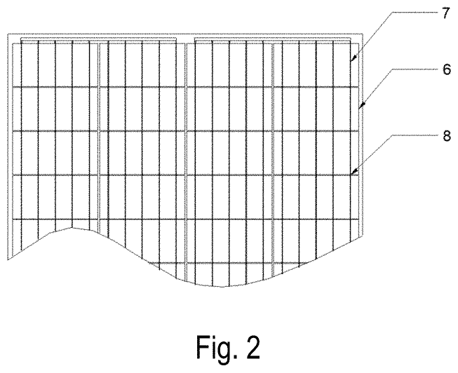

According to some embodiments of the disclosure, as shown in FIG. 1 and FIG. 2, the layer 1 denotes a surface glass layer; the layer 2 denotes an upper encapsulation layer; the layer 3 denotes a solar cell string layer; the layer 4 denotes a lower encapsulation layer; the plate 5 denotes a back plate; 6 denotes a solar cell; the conductor 7 denotes a first electric conductor; the conductor 8 denotes a second electric conductor; and 9 denotes a reflective film.

### DETAILED DESCRIPTION

Exemplary embodiments of the disclosure will be described below in more detail with reference to the accompanying drawings. Although the accompanying drawings show exemplary embodiments, it should be understood that the disclosed embodiments may be implemented in various forms and should not be limited by the specific embodiments described herein. Instead, the disclosed embodiments are provided so that the disclosure will be better understood, and the scope of the disclosure can be fully conveyed to a person skilled in the art.

In some embodiments, as shown in FIG. 1 and FIG. 2, a high efficient photovoltaic module with cut cells can include: a surface glass layer 1, an upper encapsulation layer 2, a solar cell string layer 3, a lower encapsulation layer 4, and a back plate 5 disposed sequentially from top to bottom. The solar cell string layer can include a plurality of solar cell strings. For example, the solar cell string can include a plurality of solar cells 6 connected by using a first electric conductor 7 and a second electric conductor 8. The solar cells can be cut cells. The solar cells can be connected in series by the first electric conductor on front sides, and the solar cells can be connected in series by the second electric conductor on back sides.

For example, the solar cells in the solar cell string can include P-type cells and N-type cells. In some embodiments, in the same solar cell string, the P-type cells and the N-type cells can be arranged alternately. In this arrangement manner, two surfaces of a P-type cell and an N-type cell adjacent to each other on the same side have different polarities. For example, the front-side polarity of the P-type cell is negative, and the front-side polarity of the N-type cell is positive. Therefore, front sides of the adjacent P-type cell and N-type cell can be connected by using the first electric conductor, thus achieving the serial connection of the two cells. Likewise, the serial connection of the two cells can also be achieved by connecting back sides of the adjacent P-type cell and N-type cell by using the second electric conductor. In some embodiments, the second electric conductor can be used for connection on the back sides of the cells, and therefore, the use of the second electric conductor having a larger cross-sectional area can reduce the series resistance of the module, thereby reducing the electrical loss caused by the resistance. In some embodiments, the cut cells in the module can be half-cells, such that the operating current in a single cell string can be one-half of that of a conventional cell, and in addition to the reduced series resistance of the module, the electrical loss in the module encapsulation process can be reduced significantly.

In some embodiments, a reflective film can be disposed on the front side of the first electric conductor, and the reflective film can enable most of the light emitted to this region to be reflected to the surface of the solar cell and reabsorbed for use, thereby reducing the optical loss caused by blocking of light by the first electric conductor. In some embodiments, the cells in the module can be cut cells; therefore, a larger gap area exists between the cells, and the reflection of light in this region can be increased. The superposition of the two kinds of reflection greatly increases the utilization rate of the solar cell regarding the light energy, thus significantly reducing the optical loss. Therefore, by reducing the electrical loss and the optical loss in the module encapsulation process, the maximum output power and the conversion efficiency of the module are greatly improved.

In addition, for example, a fabricating method of the photovoltaic module is further provided, including the following steps of:

(1) alternately arranging a plurality of P-type cut cells and N-type cut cells, using a first electric conductor to achieve connection between adjacent cells on front sides, using a second electric conductor to achieve connection between the adjacent cells on back sides, and connecting the solar cells in series to form a solar cell string;

(2) laying a surface glass layer, an upper encapsulation layer, a plurality of solar cell strings, a lower encapsulation layer, and a back plate sequentially from bottom to top, and connecting the solar cell strings by using metal components; and

(3) placing the stacked component layers into a laminating machine and laminating the layers in high-temperature vacuum, cross-linking and curing the upper encapsulation layer and the lower encapsulation layer, and bonding the material and component layers into a whole to obtain the photovoltaic module.

The above implementations are merely exemplary implementations employed to explain the principles of the current disclosure, and the current disclosure is not limited thereto. For a person skilled in the art, various changes or improvements can be made according to the above-mentioned content of the current disclosure, according to the prior art and knowledge in the art, and with reference to the basic idea of the current disclosure. Such changes or improvements should fall within the protection scope of the current disclosure.

What is claimed is:

1. An apparatus, comprising:
a photovoltaic module, comprising:
a surface glass layer;
an upper encapsulation layer;
a solar cell string layer;
a lower encapsulation layer; and
a back plate.

2. The apparatus according to claim 1, wherein the solar cell string layer comprises a plurality of solar cell strings, each solar cell string comprising a plurality of solar cells connected by using a first electric conductor and a second electric conductor.

3. The apparatus according to claim 2, wherein the plurality of solar cells is cut cells.

4. The apparatus according to claim 2, wherein the plurality of solar cells is connected in series by the first electric conductor on front sides.

5. The apparatus according to claim 2, wherein the plurality of solar cells is connected in series by the second electric conductor on back sides.

6. The apparatus according to claim 2, wherein the plurality of solar cells in the solar cell string comprise P-type cells and N-type cells.

7. The apparatus according to claim 6, wherein the P-type cells and the N-type cells are arranged alternately.

8. The apparatus according to claim 6, wherein the P-type cell and the N-type cell adjacent to each other are connected to each other by the first electric conductor on the front sides thereof and are connected to each other by the second electric conductor on the back sides thereof.

9. The apparatus according to claim 2, wherein the P-type cell and the N-type cell adjacent to each other are connected to each other by the second electric conductor on the back sides thereof.

10. The apparatus according to claim 2, wherein the first electric conductor and the second electric conductor have different cross sections.

11. The apparatus according to claim 10, wherein the cross-sectional area of the first electric conductor is smaller than the cross-sectional area of the second electric conductor.

12. The apparatus according to claim 2, wherein the first electric conductor and the second electric conductor are tin-coated copper strips or conductive paste.

13. The apparatus according to claim 2, wherein a front side of the first electric conductor is provided with a reflective film.

14. The apparatus according to claim 2, wherein the solar cell is a half-cell or a 1/n-cell, wherein n is greater than or equal to 3.

15. The apparatus according to claim 2, wherein the solar cells in the same solar cell string have the same size.

16. The apparatus according to claim 1, wherein the front-side encapsulation layer and back-side encapsulation layer are made from ethylene vinyl acetate copolymer, polyolefin, polyvinyl butyral, or silicone.

17. An apparatus, comprising:
a surface glass layer;
an upper encapsulation layer;
a solar cell string layer;
a lower encapsulation layer; and
a back plate, wherein the solar cell string layer comprises a plurality of solar cell strings, each solar cell string comprising a plurality of solar cells connected by using a first electric conductor and a second electric conductor.

18. The apparatus according to claim 17, wherein the plurality of solar cells is connected in series by the first electric conductor on front sides.

19. The apparatus according to claim 17, wherein the plurality of solar cells is connected in series by the second electric conductor on back sides.

20. A method for fabricating a photovoltaic module, the method comprising:
arranging a plurality of P-type cut cells and N-type cut cells alternately;
connecting adjacent cells on front sides by using a first electric conductor;
connecting the adjacent cells on back sides by using a second electric conductor;
connecting the solar cells in series to form a solar cell string;
laying a surface glass layer, an upper encapsulation layer, a plurality of solar cell strings, a lower encapsulation layer, and a back plate sequentially from bottom to top;
connecting the solar cell strings by using metal components;
placing the stacked component layers into a laminating machine;
laminating the layers in high-temperature vacuum;
cross-linking and curing the upper encapsulation layer and the lower encapsulation layer; and
bonding the material and component layers into a whole to obtain the photovoltaic module.
